(19) United States
(12) Patent Application Publication
(10) Pub. No.: US 2006/0145095 A1
(43) Pub. Date: Jul. 6, 2006

(54) Methods and apparatus for ion implantation with control of incidence angle by beam deflection

(75) Inventors: Joseph C. Olson, Beverly, MA (US); Anthony Renau, West Newbury, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 11/027,371

(22) Filed: Dec. 30, 2004

(51) Int. Cl. H01J 37/08

(52) U.S. Cl. 250/492.21

(57) ABSTRACT

A method for implanting ions into a workpiece, such as a semiconductor wafer, includes generating an ion beam, providing a workpiece support surface to support a workpiece during ion implantation, deflecting the ion beam to provide a desired incidence angle of the deflected ion beam relative to the workpiece support surface, and performing an implant with the ion beam deflected at the desired incidence angle relative to the workpiece support surface. The incidence angle may be measured, and the beam deflection may be adjusted based on a comparison of the measured incidence angle and the desired incidence angle.

### FIELD OF THE INVENTION

This invention relates to systems and methods for ion implantation of semiconductor wafers and other workpieces and, more particularly, to methods and apparatus for ion implantation at a desired incidence angle.

### BACKGROUND OF THE INVENTION

Ion implantation is a standard technique for introducing conductivity-altering impurities into semiconductor wafers. A desired impurity material is ionized in an ion source, the ions are accelerated to form an ion beam of prescribed energy, and the ion beam is directed at the surface of the wafer. The energetic ions in the beam penetrate into the bulk of the semiconductor material and are embedded into the crystalline lattice of the semiconductor material to form a region of desired conductivity.

Ion implantation systems usually include an ion source for converting a gas or a solid material into a well-defined ion beam. The ion beam is mass analyzed to eliminate undesired ions species, is accelerated to a desired energy and is directed onto a target plane. The beam is distributed over the target by beam scanning, by target movement, or by a combination of beam scanning and target movement.

Ion implanters are frequently required to tilt the wafer relative to the incident ion beam. The tilt angle establishes the incidence angle of the ion beam on the wafer surface. In some applications, the tilt angle is used to control channeling of implanted ions in the crystalline structure of the semiconductor wafer. For example, a tilt angle of seven degrees is commonly used in the case of silicon semiconductor wafers. In other applications, the tilt angle is related to the geometry of the semiconductor device being implanted. For example, a tilt angle maybe utilized to implant ions under the gate of an MOS device.

The semiconductor wafer is typically mounted on a support surface of a platen that can be tilted relative to the ion beam. In some instances, the wafer is tilted about a single axis, whereas in other systems the wafer may be tilted about two orthogonal axes to achieve a desired incidence angle of the ion beam on the wafer surface. However, the suitability of the tilt mechanism is closely related to the type of scanning utilized in the ion implanter.

A method for ion implantation wherein a wafer is tilted at an angle referenced to a measured beam direction is disclosed in U.S. Pat. No. 6,437,350, issued Aug. 20, 2002 to Olson et al. A method for ion implantation wherein a wafer is tilted about an X-axis that is parallel to the plane of a scanned ion beam is disclosed in U.S. Pat. No. 6,163,033, issued Dec. 19, 2000 to Smick et al.

Ion implanters have been introduced which utilize a fixed spot beam and two-dimensional mechanical scanning of the semiconductor wafer to distribute the ion beam over the wafer. The platen that holds the wafer during ion implantation may be tilted about a horizontal axis, and mechanical scanning is performed in the plane of the tilted wafer. This configuration is limited to tilting the wafer about a single axis. However, some applications may have additional requirements with respect to incidence angle.

Accordingly, there is a need for improved methods and apparatus for ion implantation with a desired incidence angle of the ion beam on the wafer surface.

### SUMMARY OF THE INVENTION

According to a first aspect of the invention, a method is provided for implanting ions into a workpiece. The method comprises generating an ion beam, providing a workpiece support surface to support a workpiece during ion implantation, deflecting the ion beam to provide a desired incidence angle of the deflected ion beam relative to the workpiece support surface, and performing an implant with the ion beam deflected at the desired incidence angle relative to the workpiece support surface.

According to a second aspect of the invention, apparatus is provided for implanting ions into a workpiece. The apparatus comprises an ion beam generator configured to generate an ion beam, a workpiece support surface having a surface configured to support a workpiece for ion implantation, and a beam deflector configured to deflect the ion beam to provide a desired incidence angle of the deflected beam on the support surface, wherein an implant is performed with the ion beam deflected at the desired incidence angle.

According to a third aspect of the invention, a method is provided for implanting ions into a semiconductor wafer. The method comprises generating an ion beam; providing a wafer support surface to support a semiconductor wafer; deflecting the ion beam to provide a desired incidence angle of the deflected beam relative to the wafer support surface; rotating the wafer support surface to provide a desired orientation between the deflected ion beam and the wafer; and performing an implant with the ion beam deflected at the desired incidence angle relative to the wafer support surface. The method may further include tilting the wafer relative to the deflected ion beam.

### BRIEF DESCRIPTION OF THE DRAWINGS

For a better understanding of the present invention, reference is made to the accompanying drawings, which are incorporated herein by reference and in which:

FIG. 1 is a schematic block diagram of an ion implanter in accordance with an embodiment of the invention;

FIG. 2 is a schematic diagram of a semiconductor wafer and incident ion beam, which illustrates embodiments of the present invention;

FIG. 3 is a schematic diagram of a first prior art technique for performing a tilted implant;

FIG. 4 is a schematic diagram of a second prior art technique for performing a tilted implant;

FIG. 5 is a schematic diagram of a technique for performing an implant with a deflected ion beam in accordance with an embodiment of the invention;

FIG. 6 is a schematic diagram of a technique for performing an implant with a deflected ion beam and a tilted wafer in accordance with an embodiment of the invention;

FIG. 7 is a schematic diagram that illustrates an ion beam deflected at different angles and corresponding wafer positions for ion implantation;

FIG. 8 is a flow chart of a process for ion implantation in accordance with an embodiment of the invention; and

FIG. 9 is a schematic block diagram of an ion implanter in accordance with an embodiment of the invention.

### DETAILED DESCRIPTION

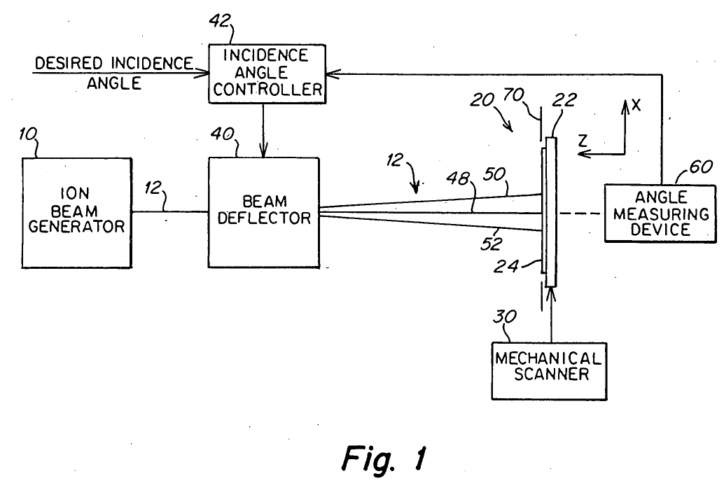

A simplified block diagram of an ion implanter in accordance with an embodiment of the invention is shown in FIG. 1. An ion beam generator 10 generates an ion beam of a desired species, accelerates ions in the ion beam to desired energies, performs mass/energy analysis of the ion beam to remove energy and mass contaminants, and supplies an energetic ion beam 12. An end station 20 includes a platen 22 that supports a semiconductor wafer 24 or other workpiece in the path of ion beam 12 such that ions of the desired species are implanted into the semiconductor wafer 24. The ion implanter may include additional components well known to those skilled in the art. For example, end station 20 typically includes automated wafer handling equipment for introducing wafers into the ion implanter and for removing wafers after implantation, a dose measuring system, an electron flood gun, etc. It will be understood that the entire path traversed by the ion beam is evacuated during ion implantation.

In the embodiment of FIG. 1, ion beam 12 is held stationary during ion implantation and wafer 24 is translated in two dimensions to distribute the ion beam over the wafer. A mechanical scanner 30 translates platen 22 and wafer 24 in two dimensions relative to ion beam 12.

The ion implanter of FIG. 1 further includes a beam deflector 40 which deflects ion beam 12 along a selected beam path in response to an incidence angle controller 42. As shown in FIG. 1, ion beam 12 may be transported along a beam path 48 when not deflected, may be deflected to a first beam path 50 in response to a first control value from incidence angle controller 42 and may be deflected to a second beam path 52 in response to a second control value. Each beam path is incident on wafer 24 at a different incidence angle, as discussed below. Beam deflector 40 establishes an incidence angle of ion beam 12 on wafer 24. The incidence angle may be continuously variable in response to a variable control value supplied by incidence angle controller 42. Deflection of ion beam 12 is equivalent to tilting wafer 24 relative to ion beam 12.

Beam deflector 40 may be an electrostatic deflector or a magnetic deflector, as known to those skilled in the art. In the case of an electrostatic deflector, the beam deflection is established by a voltage applied to electrostatic deflection plates. In a case of a magnetic deflector, the beam deflection is established by a current applied to the coil of an electromagnet.

End station 20 may include an angle measuring device 60 for measuring the incidence angle of ion beam 12 on a target plane 70 defined by platen 22. A device for measuring incidence angle (beam direction) is disclosed, for example, in U.S. Pat. No. 6,437,350, which is hereby incorporated by reference. Incidence angle controller 42 receives a desired incidence angle as a user input or a recipe input and receives a measured angle from angle measuring device 60. The desired incidence angle and the measured incidence angle may be compared by incidence angle controller 42 to determine an adjusted beam deflection, so that the desired incidence angle is achieved. In particular, the difference between the desired incidence angle and the measured incidence angle defines an incidence angle error. The beam deflection may be adjusted to reduce or eliminate the incidence angle error. It will be understood that the incidence angle is measured and the beam deflection is adjusted before ion implantation or between ion implantations of individual wafers.

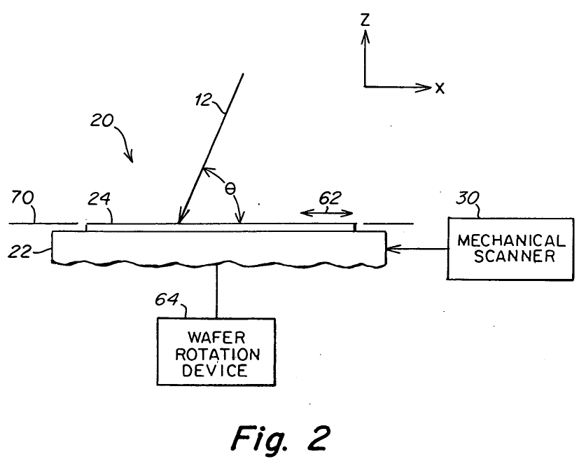

An enlarged partial view of end station 20 is shown in FIG. 2. Ion beam 12 is deflected to provide an incidence angle θ relative to target plane 70. Incidence angle θ is maintained fixed during ion implantation of wafer 24. In particular, wafer 24 may be translated in two dimensions by mechanical scanner 30 parallel to target plane 70, as indicated by arrows 62. Ion beam 12 is thereby distributed over the surface of wafer 24, preferably with a uniform distribution, while maintaining incidence angle θ.

As shown in FIG. 2, incidence angle θ is defined in a Z-X plane. Additional wafer motions may be provided within the scope of the present invention. For example, platen 22 and wafer 24 may be tilted about the X-axis to provide an additional degree of freedom in orienting wafer 24 relative to ion beam 12. In addition, end station 20 may include a wafer rotation device 64 for rotating wafer 24 about an axis perpendicular to target plane 70. Wafer rotation device 64 may be utilized to orient wafer 24 relative to deflected ion beam 12.

Specification of rotation of the wafer as well its tilt is required in order to perform most tilted implants correctly. This may be due to details of the crystalline structure of the wafer, the configuration of structures on the wafer surface, or both. For example, implantation of a sidewall of a trench or a raised feature on a semiconductor device requires a specific orientation of the ion beam with respect to the sidewall. The required orientation is achieved by rotation of the wafer.

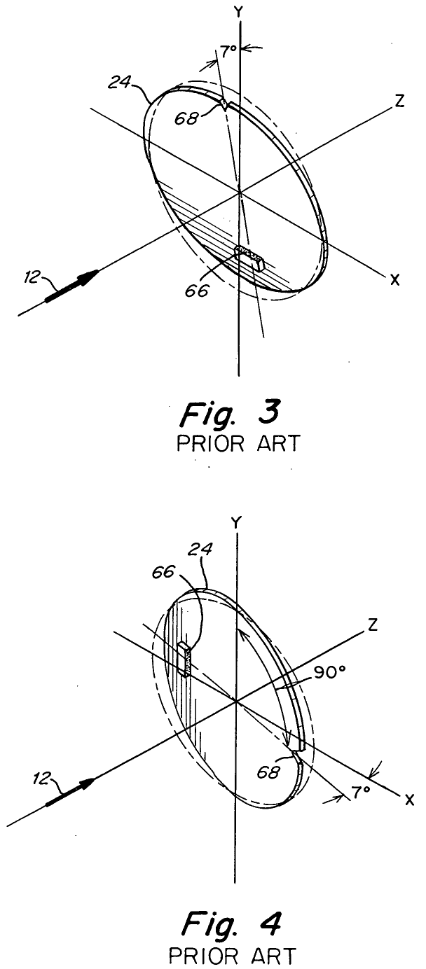

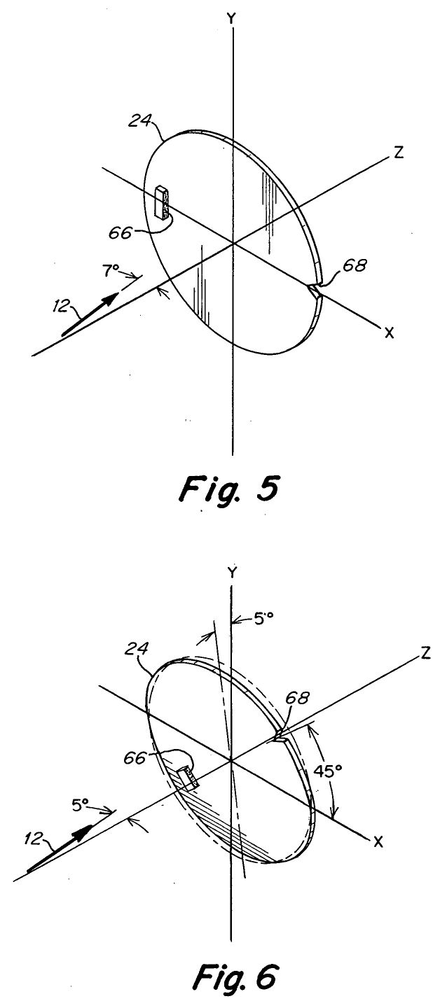

FIGS. 4-7 illustrate four ways of performing the same implant, namely one where the angle between the wafer and the ion beam is 7° and the wafer is rotated so that a feature 66, such as a sidewall, is implanted. FIGS. 3 and 4 illustrate prior art implant techniques, and FIGS. 5 and 6 illustrate implant techniques in accordance with embodiments of the invention.

In FIG. 3, the ion beam 12 is aligned with the Z axis and the wafer 24 is tilted about the X axis by 7°. The wafer is rotated such that notch 68 is on the Y axis.

In FIG. 4, wafer 24 has been rotated by 90° relative to FIG. 3 such that notch 68 is on the X axis. The beam is aligned with the Z axis, and the wafer is tilted about the Y axis by 7° for feature 66 to be implanted.

In FIG. 5, ion beam 12 forms a 7° angle with respect to Z axis in the X-Z plane. The 7° angle can be achieved by beam deflection as described herein. The wafer is not tilted and remains in the X-Y plane but may be rotated, if necessary, so that notch 68 is on the X axis. Feature 66 is implanted at an angle of 7° due to the angle of ion beam 12 with respect to the Z axis.

The deflection of ion beam 12 and tilting of wafer 24 can be combined to give desired implant conditions as shown in FIG. 6. In the example of FIG. 6, ion beam 12 forms a 5° angle with respect to the Z axis in the X-Z plane. The wafer is tilted by 5° about the X axis and is rotated by 45° from the Y axis to achieve a 7° implant angle. It can be shown by geometric analysis that a 5° beam deflection, a 5° tilt of wafer 24 and a 45° rotation of wafer 24 produces a 7° implant angle that is equivalent to those shown in FIGS. 3-5 and described above. In FIG. 6, the deflection angle of ion beam 12 is in the X-Z plane and the 5° tilt angle of wafer 24 is in the Y-Z plane. It may be noted that a combination of beam deflection, wafer tilt and wafer rotation can produce a larger implant angle than beam deflection alone or wafer tilt alone. It will be understood that the 7° implant angle is illustrated in FIGS. 3-6 by way of example only and that other implant angles can be achieved in the same manner.

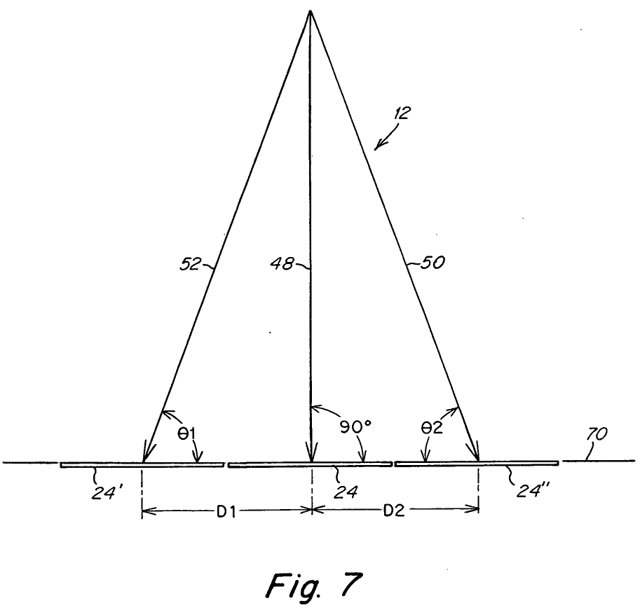

Different deflections of ion beam 12 to produce different incidence angles are shown in the schematic diagram of FIG. 7. Ion beam 12 directed along beam path 48 is incident on target plane 70 at an incidence angle of 90 degrees; ion beam 12 deflected along beam path 50 is incident on target plane 70 at an incidence angle θ2; and ion beam 12 deflected along beam path 52 is incident on target plane 70 at incidence angle θ1. It will be understood that the undeflected ion beam 12 may be incident on target plane 70 at 90 degrees or at some other angle.

Ion beam 12 is incident on target plane 70 at different locations depending on the amount of deflection and the corresponding incidence angle. The start and end points of the scan are adjusted to compensate for the displacement of ion beam 12 at different incidence angles. Typically, the scan is configured so that the ion beam 12 is completely off the wafer 24 at each end of a scan line. This approach reduces the risk of nonuniformities near the edge of the wafer. In order to compensate for displacement of the deflected ion beam 12, wafer 24 may be displaced by a distance equal to the displacement of ion beam 12 in target plane 70 and then mechanically scanned. Referring again to FIG. 7, wafers 24, 24′ and 24″ are shown in positions corresponding to incidence angles of 96 degrees, θ1 and θ2, respectively. During an implant, the wafer is positioned in target plane 70. In the case of normal incidence, wafer 24 is mechanically scanned to distribute ion beam 12 over the surface of wafer 24. In the case of incidence angle θ1, wafer 24′ is displaced to the left by a distance D1 from the position of normal incidence and is mechanically scanned to distribute ion beam 12 over the surface of wafer 24′. In the case of incidence angle θ2, wafer 24″ is displaced to the right by a distance D2 from the position of normal incidence and is mechanically scanned to distribute ion beam 12 over the surface of wafer 24″. By displacing the wafer in this manner, deflected ion beam 12 is distributed over the entire surface of the wafer independent of incidence angle.

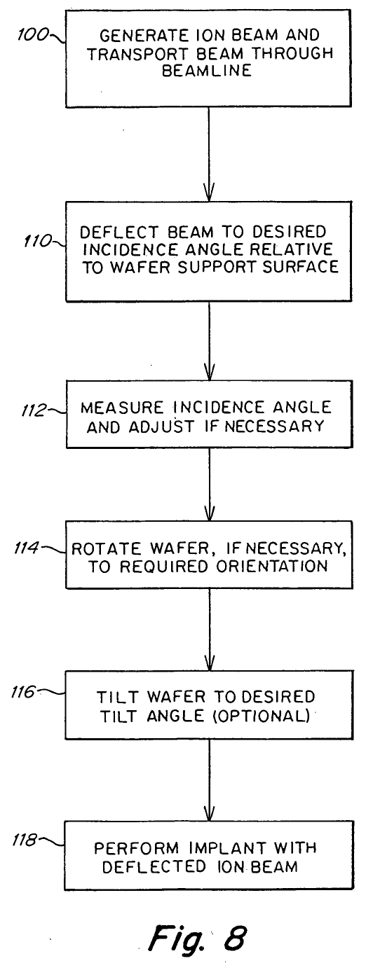

A flow chart of a method for ion implantation in accordance with an embodiment of the invention is shown in FIG. 8. In step 100, an ion beam is generated and is transported through a beamline of the ion implanter. The beamline may include an ion source, a mass/energy analyzer and an accelerator, for example. Other beamline components may be included within the scope of the present invention. In step 110, the ion beam is deflected to a desired incidence angle relative to a wafer support surface, or a target plane. The ion beam may be deflected by a dedicated beam deflector 40 as shown in FIG. 1 and described above or by a beamline component that has other functions. As described below, the ion beam may be deflected by an analyzer magnet and/or a manipulator electrode of an ion source, for example. In step 112, the incidence angle on the target plane is measured by angle measuring device 60. The measured incidence angle may be compared with a desired incidence angle. If the measured and desired incidence angles differ, the beam deflection may be adjusted to provide the desired incidence angle. In cases where the incidence angle is known and repeatable for a given set of implant conditions and deflection parameters, measurement step 112 may be omitted. In step 114, wafer 24 is rotated, if necessary, to a desired orientation relative to the deflected ion beam. In step 116, wafer 24 may be tilted with respect to the ion beam. The wafer 24 may be tilted about the X axis or the Y axis. The tilt step 116 is optional, depending on the required implant. In step 118, an implant is performed with the deflected ion beam. The implant involves distributing the deflected ion beam over the surface of wafer 24 and continuing the implant until a desired ion dose is reached. Techniques for measuring and controlling ion dose and dose uniformity are well known to those skilled in the art. It will be understood that the beam deflection of step 110, the wafer rotation of step 114 and the wafer tilt of step 116 may be performed in any order prior to the implant step 118.

Different scanning techniques may be utilized within the scope of the invention to perform the implant in step 118 of FIG. 8. The ion implanter shown in FIG. 1 and described above utilizes a stationary spot ion beam and two-dimensional mechanical scanning of the wafer to distribute the ion beam over the wafer surface. In another embodiment, the ion beam is shaped into a so-called ribbon ion beam which has a cross section that is elongated in one dimension. The ribbon ion beam is deflected to provide the desired incidence angle of the ribbon ion beam on wafer 24, and wafer 24 is mechanically scanned in a direction perpendicular to the long dimension of the ribbon ion beam cross section. In a further embodiment, the ion beam is scanned in one direction, and the ion beam is deflected as described above to provide the desired incidence angle of the scanned beam on wafer 24. The wafer 24 is mechanically scanned in a direction perpendicular to the beam scan to distribute the ion beam over the wafer surface. In each of the above embodiments, ion beam 12 remains at the desired incidence angle as it is distributed over the wafer surface.

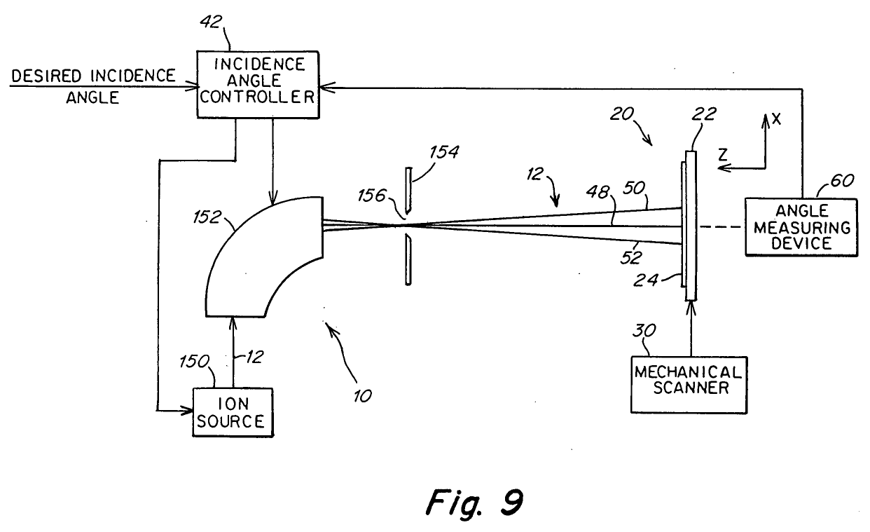

A simplified block diagram of an ion implanter in accordance with a further embodiment of the invention is illustrated in FIG. 9. Like elements in FIGS. 1 and 9 have the same reference numerals. In the embodiment of FIG. 9, ion beam generator 10 includes an ion source 150, an analyzer magnet 152 and an aperture plate 154. Ion source 150 generates ion beam 12, and the ion beam is mass analyzed by analyzer magnet 152 and aperture plate 154 to remove unwanted species. Analyzer magnet 152 deflects ions of different masses through different angles. Ions of the desired mass pass through a resolving slit 156 in aperture plate 154 and are transported to wafer 24. Undesired ion species are blocked by aperture plate 154.

In the embodiment of FIG. 9, existing components of the ion implanter are utilized to provide beam deflection to the desired incidence angle. Thus, a separate beam deflector, as shown in FIG. 1, is not required to provide the desired incidence angle. In particular, incidence angle controller 42 may control analyzer magnet 152 to deflect ion beam 12 to the desired incidence angle. Thus, the magnet current supplied to analyzer magnet 152 may be adjusted to control incidence angle. Because the ion beam is focused on slit 156, the deflected beam of the desired species is transported through the beamline to wafer 24. In other embodiments, ion source 150 may be utilized to control the incidence angle of ion beam 12 on wafer 24. In particular, ion source 150 may include a manipulator electrode which is utilized to adjust the position of ion beam 12 in the beamline. The manipulator electrode may be adjusted to provide a desired beam deflection. Adjustments of analyzer magnet 152 and ion source 150 may be utilized separately or in combination to provide the desired incidence angle.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for implanting ions into a workpiece, comprising:
generating an ion beam;
providing a workpiece support surface to support a workpiece;
deflecting the ion beam to provide a desired incidence angle of the deflected ion beam relative to the workpiece support surface; and
performing an implant with the ion beam deflected at the desired incidence angle relative to the workpiece support surface.

2. A method as defined in claim 1, wherein performing an implant comprises translating the workpiece parallel to the workpiece support surface to distribute the ion beam over the workpiece.

3. A method as defined in claim 1, wherein providing a workpiece support surface comprises providing a wafer support surface to support a semiconductor wafer.

4. A method as defined in claim 3, further comprising tilting the wafer relative to the deflected ion beam.

5. A method as defined in claim 3, further comprising measuring the incidence angle of the deflected ion beam.

6. A method as defined in claim 5, further comprising adjusting deflection of the ion beam based on comparison of the measured incidence angle and the desired incidence angle.

7. A method as defined in claim 3, further comprising adjusting the ion beam for a desired parallelism.

8. A method as defined in claim 3, further comprising rotating the wafer support surface to achieve a desired orientation between the deflected ion beam and the wafer.

9. A method as defined in claim 3, further comprising scanning the ion beam at the desired incidence angle.

10. A method as defined in claim 3, wherein generating an ion beam comprises generating a ribbon ion beam.

11. A method as defined in claim 3, wherein performing an implant comprises distributing the deflected ion beam over the wafer.

12. A method as defined in claim 3, wherein performing an implant comprises mechanically translating the wafer in two dimensions to distribute the deflected ion beam over the wafer.

13. A method as defined in claim 3, further comprising tilting the wafer relative to the deflected ion beam and rotating the wafer support surface to achieve a desired orientation between the ion beam and the wafer.

14. Apparatus for implanting ions into a workpiece, comprising:
an ion beam generator configured to generate an ion beam;
a workpiece support surface having a surface configured to support a workpiece for ion implantation; and
a beam deflector configured to deflect the ion beam to provide a desired incidence angle of the deflected beam on the support surface, wherein an implant is performed with the ion beam deflected at the desired incidence angle.

15. Apparatus as defined in claim 14, further comprising a device configured to translate the workpiece parallel to the workpiece support surface to distribute the deflected ion beam over the workpiece.

16. Apparatus as defined in claim 14, further comprising a device configured to tilt the workpiece about an axis that is not parallel to the incidence angle.

17. Apparatus as defined in claim 14, wherein the workpiece support is configured to support a semiconductor wafer.

18. Apparatus as defined in claim 14, further comprising a device configured to tilt the workpiece relative to the deflected ion beam.

19. Apparatus as defined in claim 14, further comprising a device configured to measure the incidence angle of the deflected ion beam.

20. Apparatus as defined in claim 14, further comprising a device configured to adjust parallelism of the ion beam.

21. Apparatus as defined in claim 14, further comprising a device configured to rotate the workpiece support surface to achieve a desired orientation between the deflected ion beam and the workpiece.

22. Apparatus as defined in claim 14, further comprising a scanner configured to scan the ion beam at the desired incidence angle.

23. Apparatus as defined in claim 14, wherein the ion beam generator is configured to generate a ribbon ion beam.

24. Apparatus as defined in claim 14, further comprising a mechanical scanner for two-dimensional scanning of the workpiece relative to the ion beam.

25. Apparatus as defined in claim 14, wherein the beam deflector comprises an analyzer magnet.

26. Apparatus as defined in claim 14, wherein the ion beam generator includes an ion source and wherein the beam deflector comprises a manipulator electrode of the ion source.

27. Apparatus as defined in claim 14, wherein the beam deflector comprises a magnetic ion beam deflector.

28. Apparatus as defined in claim 14, wherein the beam deflector comprises electrostatic deflection plates.

29. Apparatus as defined in claim 14, further comprising an incidence angle controller configured to control the beam deflector based on the desired incidence angle.

30. Apparatus as defined in claim 19, further comprising an incidence angle controller configured to control the beam deflector based on the desired incidence angle and the measured incidence angle.

31. Apparatus as defined in claim 17, further comprising a device configured to tilt the semiconductor wafer relative to the deflected ion beam and a device configured to rotate the semiconductor wafer to achieve a desired orientation between the ion beam and the semiconductor wafer.

32. A method for implanting ions into a semiconductor wafer, comprising:
generating an ion beam;
providing a wafer support surface to support a semiconductor wafer;
deflecting the ion beam to provide a desired incidence angle of the deflected beam relative to the wafer support surface;
rotating the wafer support surface to provide a desired orientation between the deflected ion beam and the wafer; and
performing an implant with the ion beam deflected at the desired incidence angle relative to the wafer support surface.

33. A method as defined in claim 32, further comprising tilting the wafer relative to the deflected ion beam.
